(19) United States
(12) Patent Application Publication
(10) Pub. No.: US 2026/0276679 A1
(43) Pub. Date: Sep. 17, 2026

(54) MULTIPATH CIRCUIT HAVING ENHANCED FREQUENCY CROSSOVER PERFORMANCE

(71) Applicant: Allegro MicroSystems, LLC, Manchester, NH (US)

(72) Inventors: Steven Daubert, Bedford, NH (US); Srujan Shivanakere, Nashua, NH (US); Tyler Daigle, Scarborough, ME (US)

(73) Assignee: Allegro MicroSystems, LLC, Manchester, NH (US)

(21) Appl. No.: 19/076,092

(22) Filed: Mar. 11, 2025

(51) Int. Cl. G01R 15/14; G01R 15/18; G01R 15/20; G01R 19/00

(52) U.S. Cl. CPC G01R 15/142; G01R 15/181; G01R 15/202; G01R 15/205; G01R 15/207; G01R 19/0092

(57) ABSTRACT

Methods and apparatus for a multipath device, such as a current sensor. Example embodiments include a low pass filter to receive a first signal within a first frequency range for a first signal path and a second low pass filter to receive a second signal within a second frequency range for a second signal path, wherein the second frequency range is higher than the first frequency range. A network receives the filtered first signal and the filtered second signal, which has a corner frequency aligned with a crossover frequency of the network for generating a high pass output signal from the second low pass filter with a flat frequency response above the crossover frequency.

### BACKGROUND

Some known electrical current sensors use one or more magnetic field sensing elements in proximity to a current-carrying conductor to sense a magnetic field generated by the current. The magnetic field sensing elements generate an output signal having a magnitude proportional to the magnetic field induced by the current through the conductor. In some integrated circuit current sensors, the current conductor includes a loop formed by the lead frame.

Conventional current sensors sometimes employ a combination of a magnetic field transducer, such as a Hall effect element, for sensing relatively low frequency content of the current and an inductive pickup coil for sensing higher frequency content of the current in order to sense a broader current bandwidth. However, implementing such current sensors can present technical, cost, and space challenges. For example, in some previous such current sensors, offset compensation associated with an integrator in the coil signal path requires complex matching of poles and zeros and use of large components that require “off-chip” implementation (i.e., outside of the integrated circuit package).

### SUMMARY

Example embodiments of the disclosure provide methods and apparatus for wide bandwidth current sensor integrated circuits (ICs) having a magnetic field transducer path for sensing lower frequencies and an inductive coil path for sensing higher frequencies for current flowing through a primary conductor. In embodiments, a first signal path includes a Hall-effect element path to capture DC and low-frequency current information and a second signal path includes an inductive coil path to capture high-frequency current information. These paths are summed to allow for sensing of a wide frequency band with a single device. In embodiments, the second (higher frequency) path includes a low pass filter that can have a corner frequency corresponding to a crossover frequency of a crossover network.

In one aspect, a sensor comprises: a low pass filter to receive a first signal within a first frequency range for a first signal path; a second low pass filter to receive a second signal within a second frequency range for a second signal path, wherein the second frequency range is higher than the first frequency range; and a network to receive the filtered first signal and the filtered second signal, wherein the second low pass filter has a corner frequency aligned with a crossover frequency of the network for generating a high pass output signal from the second low pass filter with a flat frequency response above the crossover frequency.

A sensor can further include or more of the following features: the first low pass filter is configured to receive the first signal as an output from a magnetic field sensing element, the magnetic field sensing element comprises a Hall element, the second low pass filter is configured to receive the second signal as an output from one or more coils positioned in relation to a current conductor, the second low pass filter is configured to receive the second signal as an output from one or more coils, wherein a gain of the second signal increases with frequency, a slope of the gain of the second signal and a roll off of the second low pass filter after the corner frequency produce the flat frequency response above the crossover frequency, the second low pass filter comprises an amplifier, the second low pass filter includes a DC feedback signal comprising a low frequency low pass filter with a range from 0.1 Hz to 100 Hz, the second low pass filter includes an RC feedback network for the amplifier, an adjustable impedance component coupled between the coil and the amplifier for adjusting a gain of the amplifier, the network includes a summing amplifier to receive the filtered first and second signals, the network comprises an amplifier to provide the first low pass filter, the network includes a gain for the first signal set by an RC network coupled to the amplifier, and/or passive components in the first and second signal paths are matched in material and/or dimensions.

In another aspect, a method comprises: low pass filtering, with a first low pass filter, a first signal within a first frequency range for a first signal path; second low pass filtering, with a second low pass filter, a second signal within a second frequency range for a second signal path, wherein the second frequency range is higher than the first frequency range; and receiving, with a network, the filtered first signal and the filtered second signal, wherein the second low pass filter has a corner frequency aligned with a crossover frequency of the network for generating a high pass output signal from the second low pass filter with a flat frequency response above the crossover frequency.

A method can further include one or more of the following features: the first low pass filter is configured to receive the first signal as an output from a magnetic field sensing element, the magnetic field sensing element comprises a Hall element, the second low pass filter is configured to receive the second signal as an output from one or more coils positioned in relation to a current conductor, the second low pass filter is configured to receive the second signal as an output from one or more coils, wherein a gain of the second signal increases with frequency, a slope of the gain of the second signal and a roll off of the second low pass filter after the corner frequency produce the flat frequency response above the crossover frequency, the second low pass filter comprises an amplifier, the second low pass filter includes a DC feedback signal comprising a low frequency low pass filter with a range from 0.1 Hz to 100 Hz, the second low pass filter includes an RC feedback network for the amplifier, an adjustable impedance component coupled between the coil and the amplifier for adjusting a gain of the amplifier, the network includes a summing amplifier to receive the filtered first and second signals, the network comprises an amplifier to provide the first low pass filter, the network includes a gain for the first signal set by an RC network coupled to the amplifier, and/or passive components in the first and second signal paths are matched in material and/or dimensions.

### DESCRIPTION OF THE DRAWINGS

The foregoing features may be more fully understood from the following description of the drawings. The drawings aid in explaining and understanding the disclosed technology. Since it is often impractical or impossible to illustrate and describe every possible embodiment, the provided figures depict one or more illustrative embodiments. Accordingly, the figures are not intended to limit the scope of the broad concepts, systems and techniques described herein. Like numbers in the figures denote like elements.

FIG. 1 is an isometric view of a current sensor according to the disclosure;

FIG. 1A is a cross-sectional view of the current sensor taken along line 1A-1A of FIG. 1;

FIG. 1B is a plan view of a portion of the current sensor of FIG. 1;

FIG. 1C is a top view of a current sensor IC package having an example pinout;

FIG. 2 is a simplified schematic of a current sensor according to the disclosure;

FIG. 2A illustrates coil path gains of a known current sensor;

FIG. 3 is a block diagram an example current sensor having a first signal path and a second signal path in accordance with an example embodiment of the disclosure;

FIG. 4 is an example implementation of the second signal path of the sensor of FIG. 3;

FIG. 4A is a graphical representation of the frequency response in the second signal path (higher frequency) for the current sensor of FIG. 4; and

FIG. 5 is an example implementation of a crossover network to receive signals from the first and second signal paths.

### DETAILED DESCRIPTION

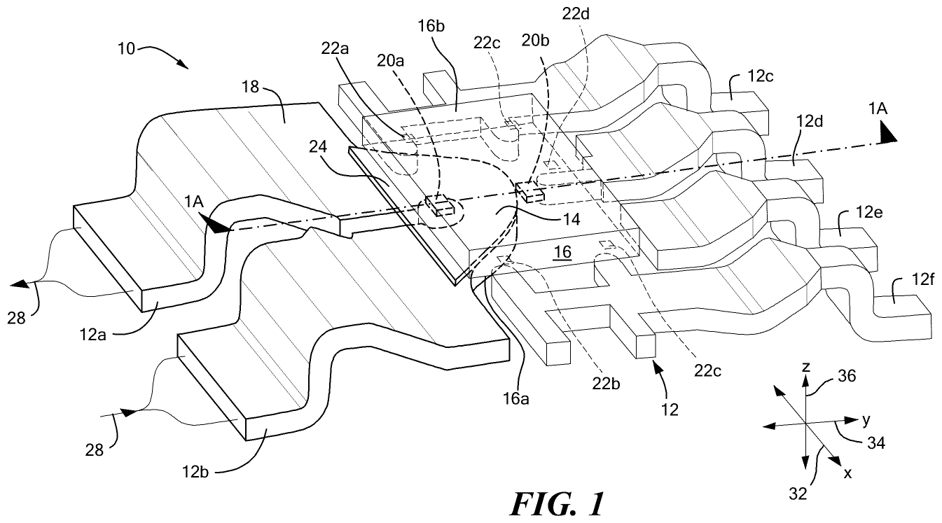

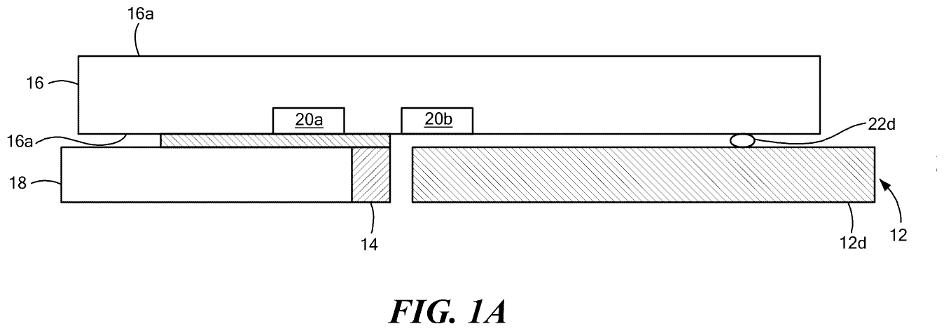

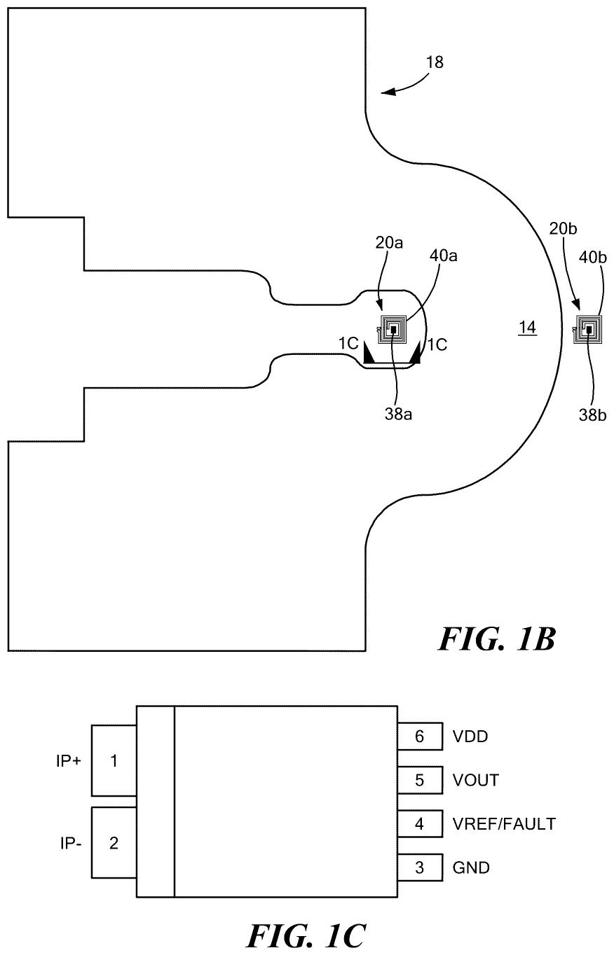

Referring to FIGS. 1, 1A, and 1B, a current sensor 10 includes a lead frame 12 having a plurality of leads 12a-12f, at least two of which leads 12a, 12b form part of a current conductor 18 configured to carry a current (illustrated by arrow 28) that generates a magnetic field. A substrate 16 has first and second opposing surfaces 16a, 16b, with the first surface 16a proximate to the current conductor 18 and the second surface 16b distal from the current conductor. A first magnetic field transducer and coil pair 20a is disposed on the first surface 16a of the substrate 16 and a second magnetic field transducer and coil pair 20b is also disposed on the first surface 16a of the substrate 16. The substrate 16 is positioned with respect to the lead frame 12 such that the first transducer and coil pair 20a is positioned on a first side of the current conductor 18 and the second transducer and coil pair 20b is positioned on a second side of the current conductor.

Conductor 18 includes leads 12a, 12b and a narrowed junction portion 14. In the example embodiment of FIG. 1, the conductor portion 14 is curved and thus transducer/coil pair 20a can be described as being positioned “inside” the curve and transducer/coil pair 20b can be described as being positioned “outside” the curve. It will be appreciated by those of ordinary skill in the art however, that other shapes and configurations of the conductor 18 including leads 12a, 12b and conductor portion 14 are possible. Furthermore, conductor 18 can include additional leads (not shown) based on application specifications.

In operation, current 28 flows into lead 12b, through conductor portion 14, and out lead 12a, thereby generating a magnetic field that is sensed by the transducer/coil pairs 20a, 20b. Processing of signals from the transducer/coil pairs 20a, 20b is explained below. Suffice it to say here to say that a first signal path coupled to receive magnetic field signals from the magnetic field transducers of the pairs 20a, 20b is configured to generate a low frequency signal associated with a low frequency content of the current 28 and a second signal path coupled to receive magnetic field signals from the coils of the pairs 20a, 20b is configured to generate a high frequency signal associated with a high frequency content of the current. Signals from the first and second paths are combined (e.g., summed) to generate an output signal of the current sensor 10 that is indicative of the current 28 through the conductor 18 and that has a wider frequency bandwidth than possible with use of only magnetic field transducers or only inductive pickup coils. For example, sensor 10 can sense current frequencies from DC to approximately 5 MHz.

As will be explained, placement of the transducer/coil pairs 20a, 20b on opposite sides of the conductor portion 14 and their design by which the pairs sense the magnetic field in opposite directions permit subtraction of their output signals to reject stray magnetic fields. A stray field (i.e., not generated by the current in the lead frame 12) will present the same magnetic field magnitude and polarity to both transducer/coil pairs 20a, 20b. Since the signals from the sensing elements are subtracted to determine the magnetic field generated by the current 28, any signal from a stray field will be removed.

Substrate 16 can be comprised of a semiconductor material such as silicon (in which case substrate 16 can be referred to as a semiconductor die or simply die) or can be comprised of any suitable material for supporting electrical elements and signals, including insulating materials. Solder balls 22a-22e on the substrate surface 16a can couple electrical elements of the current sensor disposed on or otherwise supported by the substrate to lead frame leads 12c-12f (i.e., leads other than the conductor leads 12a, 12b, which leads 12c-12f can be referred to as “signal leads”). While five solder balls 22a-22e are shown, any number of solder balls can be provided, including dummy solder balls for mechanically stabilizing the substrate 16. Also, while solder balls 22a-22e are shown, other connection methods can also be used, including, but not limited to gold bumps, eutectic or high lead solder bumps, no-lead solder bumps, gold stud bumps, polymeric conductive bumps, anisotropic conductive paste, conductive film, or wire bonds. In the case of wire bonds, bond pads can be provided on the substrate and the wire bonds can be electrically connected between the bond pads and signal leads.

In the example embodiment of FIG. 1, the substrate 16 is arranged in a so-called “flip-chip” configuration with the active surface 16a (i.e., the surface supporting the transducer/coil pairs 20a, 20b) proximate to the conductor portion 14. This configuration positions the transducer/coil pairs 20a, 20b in close proximity to the conductor portion 14. It will be appreciated by those of ordinary skill in the art however, that in other embodiments, the substrate 16 can be inverted, or flipped by 180° to provide a so-called “die-up” configuration.

Each transducer/coil pair 20a, 20b includes a magnetic field transducer and a conductive coil configured to sense magnetic field. In an example embodiment, the transducer of each pair 20a, 20b is a planar Hall effect element having a maximum response axis aligned with a z-axis 36. Thus, by positioning the transducer/coil pairs 20a, 20b on either side of the conductor portion 14 (i.e., slightly offset from the conductor portion 14 along the y-axis 34), the magnetic field in the region of the pairs 20a, 20b coincides the maximum response axis of the sensing elements. In the illustrated embodiments, the transducer/coil pairs 20a, 20b are offset (along the y-axis 34) by substantially equal and opposite amounts with respect to the current conductor portion 14. It will be appreciated by those of ordinary skill in the art however, that the transducer/coil pairs 20a, 20b may alternatively be offset (along the y-axis 34) by unequal and opposite amounts with respect to the current conductor portion 14.

It will be appreciated by those of ordinary skill in the art that the magnetic field experienced by the first and the second transducers of the pairs 20a, 20b is oriented in opposite directions. Therefore, the outputs of the transducers of the two pairs 20a, 20b will be opposite in polarity. This configuration can provide advantages of increased sensitivity and immunity to stray magnetic fields.

It will be appreciated that while magnetic field sensing elements in the form of Hall effect elements are described in connection with example embodiments, other magnetic field transducers may alternatively or additionally be used. For example, the magnetic field sensing element can be, but is not limited to, a Hall effect element, a magnetoresistance element, or a magnetotransistor. As is known, there are different types of Hall effect elements, for example, a planar Hall element, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half-bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

As is known, some of the above-described magnetic field sensing elements tend to have an axis of maximum sensitivity parallel to the surface of a substrate that supports the magnetic field sensing element, and others of the above-described magnetic field sensing elements tend to have an axis of maximum sensitivity perpendicular to the surface of a substrate that supports the magnetic field sensing element. In particular, planar Hall elements tend to have axes of sensitivity perpendicular to a substrate (i.e., along the z-axis 36), while metal based or metallic magnetoresistance elements (e.g., GMR, TMR, AMR) and vertical Hall elements tend to have axes of sensitivity parallel to a substrate (i.e., along the y-axis 34). Thus, in embodiments employing magnetic field sensing elements other than planar Hall effect elements, positioning the elements with respect to the conductor portion 14 can be tailored to optimize sensitivity.

An insulator 24 is disposed between the substrate 16 from the lead frame 12 to provide electrical isolation between the current conductor 18 and the substrate 16. The insulator 24 can be provided in a variety of ways by a variety of materials. For example, insulating layer 24 can be comprised of tape, such as a polymer Kapton® tape. It will be appreciated by those of ordinary skill in the art that, with respect to the lead frame 12, the insulating layer 24 can extend beyond the substrate 16 in a direction along the y-axis 34 to enhance the resulting electrical isolation.

Referring also to the cross-sectional view of FIG. 1A taken along line 1A-1A of FIG. 1, the flip-chip configuration of current sensor 10 can be seen, in which the transducer/coil pairs 20a, 20b are disposed on the first surface 16a of the substrate 16 proximate to the conductor 18. In particular, transducer/coil pairs 20a, 20b are positioned on either side of conductor portion 14. Also visible in FIG. 1A is the solder bump coupling of the substrate 16 to signal lead (e.g., example solder bump 22d and signal lead 12d).

Referring to the plan view of FIG. 1B, a portion of the current sensor 10 is shown to illustrate the positioning of the transducer/coil pairs 20a, 20b relative to the conductor 18. Substrate 16 is omitted from the view of FIG. 1B to facilitate illustration. As shown, each transducer/coil pair 20a, 20b includes a magnetic field transducer (e.g., Hall effect element) 38a, 38b and a coil 40a, 40b, respectively. Each of coils 40a, 40b can be formed by one or more metal traces wound in a generally spiral configuration as shown in the view of FIG. 1B. While the illustrated coils 40a, 40b each have three turns, the number of turns, or loops of each coil can be varied. While generally, more turns are desirable in order to generate a larger signal, the feasible number of turns can be limited by various factors such as chip area, maximum signal, and/or resistance of the coil. Further, while the spiral coil 40a has a generally square shape, it will be appreciated that other shapes are possible.

Each transducer 38a, 38b is positioned concentrically within respect to an innermost loop of the respective coil 40a, 40b, as shown. Positioning of the Hall effect elements 38a, 38b in the center of the respective coils 40a, 40b maximizes coupling in the sense that both the Hall effect elements 38a, 38b and the coils 40a, 40b will experience substantially the same magnetic field and maintains such coupling even over variations in placement of the pairs 20a, 20b relative the conductor portion 14. In other words, even if the transducer/coil pairs 20a, 20b shift along the y-axis with respect to the conductor portion 14 (e.g., even if placement of the die 16 on the lead frame 12 varies due to manufacturing tolerances), both the transducer generated signals and the coil generated signals will be indicative of substantially the same magnetic field and thus, the Hall effect and coil sensing paths will have substantially the same sensitivity. Trim circuitry and techniques can be used to compensate or correct the Hall path and the coil path for shifts in the die placement due to manufacturing tolerances as well as other variations.

For simplicity of explanation, features of the transducer/coil pairs 20a, 20b may be explained with respect to example pair 20a; however, it will be appreciated that transducer/coil pair 20b can be substantially identical to transducer/coil pair 20a. Thus, transducer/coil pair 20b can include a transducer 38b that is the same as or similar to transducer 38a and can include a coil 40b that is the same as or similar to coil 40a.

Transducer/coil pair 20a includes an electromagnetic shield 46 disposed between the current conductor 18 and the first surface 16a of the substrate 16 on which the coils 40a, 40b are disposed in order to prevent unwanted capacitive coupling from the conductor 18 to the sensing elements 38a, 38b, 40a, 40b. A capacitively-coupled signal represents a change in the voltage potential of the lead frame 12. In some applications in which current sensor 10 can be used, such as with motor control or DC/DC converters, this voltage can change rapidly and not in response to a change in the current through conductor 18.

FIG. 1C shows an example current sensor IC package having enhanced frequency crossover in a multipath configuration. IP+ and IP− provide terminals for the primary conductor, VOUT provides a voltage signal corresponding to current, and VREF/FAULT provides an optional fault signal.

It is understood that above describes one example embodiment of a multipath sensor configuration. It is understood that other multipath sensor configurations can vary widely to meet the needs of a particular application.

In addition, while example embodiments of the disclosure are shown and described in conjunction with current sensors having heterogenous sensing paths responsive to different frequencies, it is understood that embodiments are applicable to circuits in general in which signals from different signal paths are combined in crossover network.

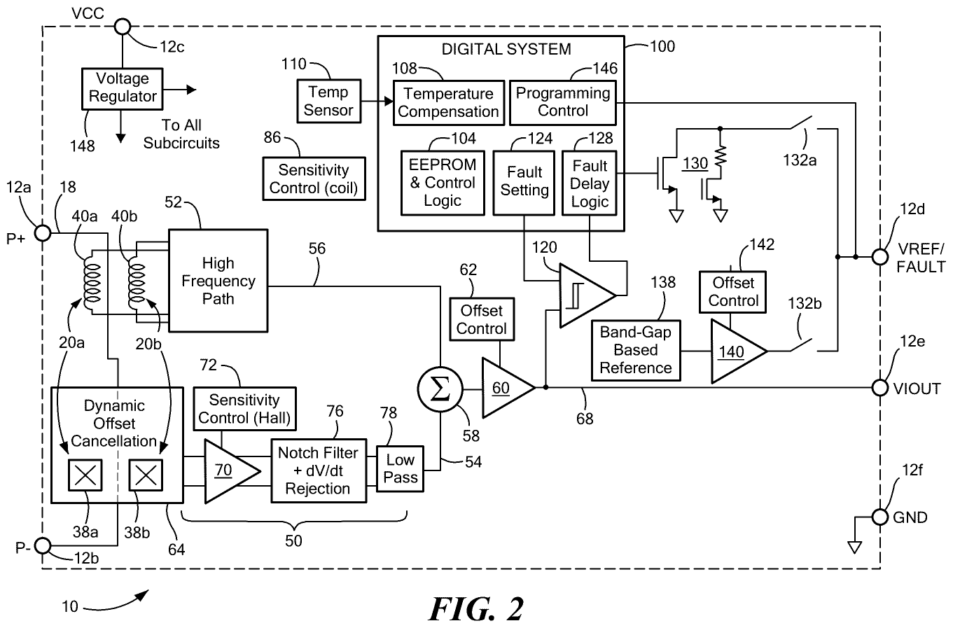

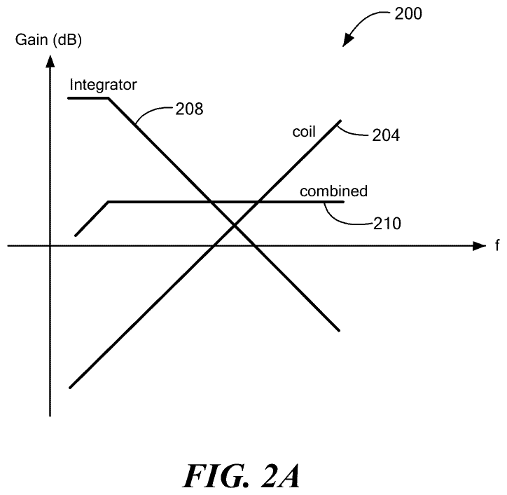

FIG. 2 shows a simplified schematic block diagram of the current sensor 10 including transducer/coil pairs 20a, 20b, with each pair pictorially shown positioned on opposite sides of current conductor 18. It will be appreciated that the signal leads 12c-12f are arbitrarily assigned to the various electrical connections and can be varied and/or more or fewer signal lead and other connections can be provided.

Transducer/coil pair 20a includes Hall effect element 38a and coil 40a and transducer/coil pair 20b includes Hall effect element 38b and coil 40b. Transducer 38a is configured to generate a first magnetic field signal and transducer 38b is configured to generate a second magnetic field signal. Coil 40a is configured to generate a third magnetic field signal and coil 40b is configured to generate a fourth magnetic field signal. Sensor 10 includes a first signal path 50 coupled to receive the magnetic field signals from transducers 38a, 38b and configured to generate a low frequency signal 54 associated with a low frequency content of the current 28 (FIG. 1) through the current conductor 18 and a second signal path 52 coupled to receive the magnetic field signals from coils 40a, 40b and configured to generate a high frequency signal 56 associated with a high frequency content of the current 28 through the current conductor 18. A cross-over network may include a summation circuit 58 configured to sum the low frequency signal 54 and the high frequency signal 56 to provide a wide bandwidth signal 68 indicative of the current through the conductor 18.

The first and second Hall effect elements 38a, 38b detect the magnetic field generated by the current 28 in opposite directions since the elements are positioned on opposite sides of the conductor portion 14. Similarly, the coils 40a, 40b detect the magnetic field generated by the current 28 in opposite directions since the coils are on opposite sides of the conductor portion 14. Signal path 50 generates the low frequency signal 54 from a differential signal generated by subtraction of the magnetic field signal from transducer 38b from the magnetic field signal from transducer 38a by operation of amplifier 70. Similarly, signal path 52 generates the high frequency signal 56 from a differential signal generated by subtraction of the magnetic field signal from coil 40b from the magnetic field signal from coil 40a. With this arrangement, since stray magnetic fields will influence elements 38a and 38b in the same way and will also influence coils 40a and 40b in the same way, use of differential signals will tend to eliminate the influence of stray magnetic fields.

The low frequency signal path 50 can include dynamic offset cancellation circuitry 64 to remove offset that can be associated with the magnetic field sensing elements 38a, 38b and/or the amplifier 70. Dynamic offset cancellation circuitry 64 may include chopping circuitry with switches configurable to drive the magnetic field sensing elements 38a, 38b in two or more different directions such that selected drive and signal contact pairs are interchanged during each phase of a chopping clock signal and offset voltages of the different driving arrangements tend to cancel.

Front-end amplifier 70 is coupled to receive offset adjusted signals from sensing elements 38a, 38b and can be responsive to a sensitivity control circuit 72 to generate an amplified signal. Sensitivity control circuit 72 can generate and provide a sensitivity control signal to the amplifier 70 to adjust a sensitivity and/or operating voltage of the amplifier.

A optional notch filter and dV/dt rejection circuit 76 can be coupled to receive the amplified signal and generate an impulse filtered signal. Low pass filter 78 can operate on the impulse filtered signal to generate the low frequency signal 54. Suffice it to say here that since the low frequency signal path has a relatively low bandwidth, an impulse disturbance can take a long time to dissipate.

The output signal of summation circuit 58 can be amplified by an amplifier 60 with further offset control by an offset control circuit 62 in order to generate the current sensor output signal 68 indicative of wide frequency band of current through conductor 18.

Additional components of current sensor 10 can include a digital system 100 containing various signal processing elements, such as an EEPROM and control logic block 104. EEPROM and control logic block 104 determines any application-specific coding and can be erased and reprogrammed using a pulsed voltage. An active temperature compensation circuit 108 can be coupled to acquire temperature data from a temperature sensor 110 and can perform calculations to compensate for changes in temperature.

Current sensor 10 can include fault detection circuitry to detect various faults and provide a FAULT output signal. For example, fault detection circuitry can detect an overcurrent condition and/or an undercurrent condition indicating that the current through conductor 18 is greater than or less than respective thresholds, respectively. To this end, a comparator 120 can be coupled to receive the current sensor output signal 68 and one or more threshold levels from a fault setting block 124. An output of comparator 120 can be coupled to a fault delay logic circuit 128 and provide a FAULT signal at an output (e.g., at signal lead 12d) via one or more drivers 130. Fault delay logic 128 can be used to process the comparator output in various ways. For example, if the comparator output indicates a fault for a very short period of time, the logic 128 can ignore it and not pass a fault signal to pin 12d. Another option is to extend the fault signal in the sense that if the comparator indicates a fault and then disappears, the logic 128 can extend the signal sent to pin 12d, ensuring that the processor monitoring 12d has adequate time to recognize the fault. An output of the current sensor at lead 12d can be a dual-purpose output at which fault detection information or a reference voltage VREF is provided by operation of complementarily controlled switches 132a, 132b. Reference voltage VREF can be provided by a bandgap reference 138 with amplification and offset control provided by elements 140, 142, respectively. A programming control block 146 can be used to control switches 132a, 132b.

A power lead 12c can be coupled to receive a supply voltage VCC for a voltage regulator 148 to generate one or more regulated voltages to power the various components and sub-circuits of the sensor 10. A ground lead 12f can be configured to couple to a reference or ground potential.

FIG. 2A 200 graphically illustrates gain associated with a conventional high frequency path having an integrator for the coil input followed by a high pass filter with a horizontal axis representing frequency in arbitrary units of Hertz and a vertical axis representing gain in arbitrary units of decibels. U.S. Pat. No. 11,366,141, which is incorporated herein by reference, shows an example high frequency signal path having an integrator. Curve 204 illustrates an example gain associated with coils, which may be similar to coils 40a, 40b in FIG. 2. Since coils 40a, 40b are inductively coupled to detect the magnetic field generated by a current through conductor, the signal strength increases with increasing frequency, as may occur at an example rate of approximately 20 dB/dec.

In order to maintain a substantially flat frequency response in a conventional high frequency sign path, the signals from coils 40a, 40b are passed through an integrator with a gain illustrated by curve 208. The integrator is designed to attenuate the signal at the same rate as the coil gain increases over frequency (e.g., at a rate of 20 dB/dec), resulting in a substantially flat gain curve 210 representing combined gain of the coils and integrator.

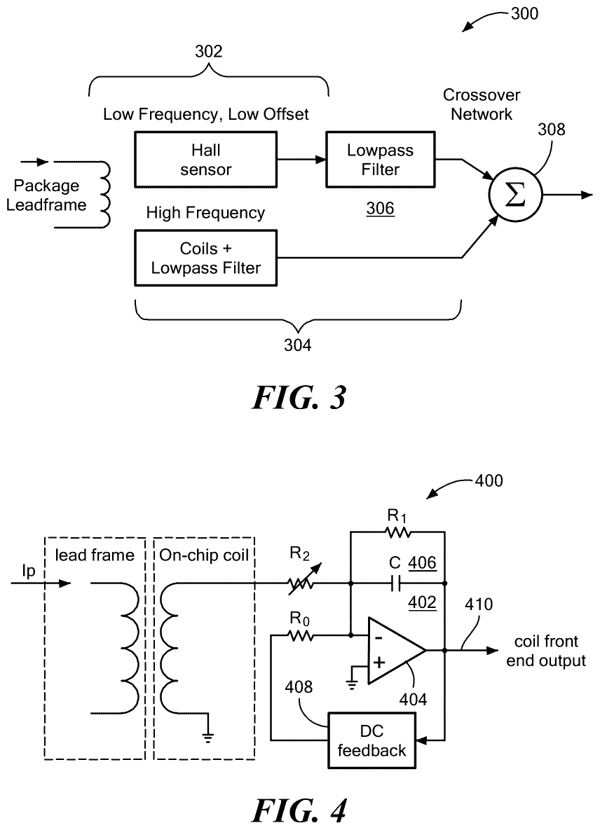

FIG. 3 shows an example embodiment 300 of a first signal path 302 and a second signal path 304 coupled to a crossover network 306. In the illustrated embodiment, the first signal path 302 is a low frequency signal path similar to signal path 50 in FIG. 2. The second signal path 304, which may correspond to path 56 in FIG. 2, combines flat gain and low pass filtering instead of a conventional crossover network having high pass and low pass combination. As described more fully below, the high frequency path 304 can be implemented with a low pass filter instead of an integrator and the crossover network 306 may include a combiner 308 in the form of a summing amplifier.

Conventional multi-path sensors can include a low frequency path and a high frequency path coupled to a crossover network to form a wide bandwidth sensor where the crossover network includes a summing amplifier with a high pass filter for the high frequency path and low pass filter for the low frequency path. This configuration works well if the corner frequency f_{crossover} of the two filters matches for both paths, and if neither path has any additional poles within 2 decades of f_{crossover}. In practice, this requirement may be challenging to achieve where the high frequency path includes a coil and an integrator since the circuitry includes a high gain amplifier to implement the integrator, and a very low frequency feedback path to cancel the amplifier's offset. This functionality is challenging to implement and may result in significant ripple in the frequency response of the overall sensor at the crossover frequency f_{crossover} due to the presence of undesired additional poles.

The example embodiment of FIG. 3 uses a flat gain and low pass filtering instead of a high pass and low pass combination. The high frequency path is implemented with a low pass filter instead of an integrator and the low pass filter corner frequency is placed at the crossover frequency f_{crossover} which reduces the amplifier requirements since the high integrator high gain (see FIG. 2A) is not needed.

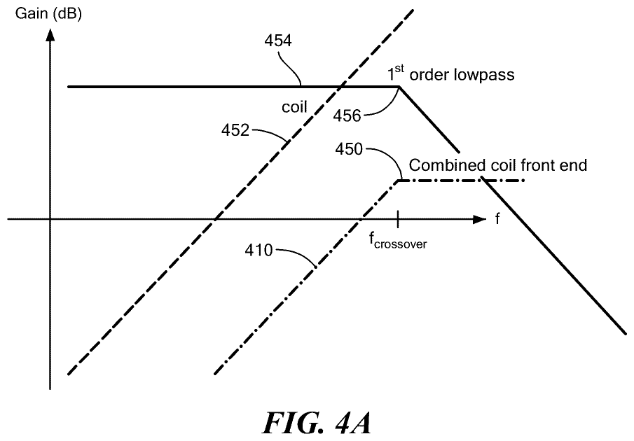

FIG. 4 shows an example implementation of a high frequency path and FIG. 4A shows an example frequency response in the form of a Bode diagram for the high frequency signal path of FIG. 4. As noted above, FIG. 2A shows the response for a conventional sensor in which the integrator needs to have high gain at low frequency to compensate for the low coil coupling which results in a flat frequency response at the output of the coil front end. It should be noted that this high gain is unnecessary, since the signal is immediately attenuated by the highpass filter in the crossover network of the conventional high pass and low pass crossover network.

FIG. 4 shows an example implementation 400 of the high frequency signal path 304 of FIG. 3. A low pass filter 402 is implemented with an amplifier 404 having an RC feedback network 406 and a DC feedback circuit 408. The coil signal is provided to the amplifier 404.

Referring to FIGS. 4 and 4A, the output 410 of the coil front end is a highpass filtered response with a corner frequency 450 set to the crossover frequency f_{crossover} of the network. In the illustrated embodiment, the high pass function is achieved for the example 20 dB/dec increasing gain of the coil 452 with a signal 454 for a first order lowpass filter 402. As can be seen, the increasing gain of the coil 452 and the filter signal 454 roll off above the crossover frequency, which has an opposite slope of the coil 454 signal, results in a flat frequency response of coil front end signal 410.

Since the lowpass filter 402 is implemented with an amplifier 404, it can provide the required gain to set the desired sensor sensitivity at the cross over frequency, but it does not require the excess gain of conventional integrator solutions. This lowering of the gain also reduces the gain of the amplifier noise at the output of the coil front end.

While shown in a single-ended circuit for simplicity, it is understood that example sensor embodiments may be differential to meet the needs of a particular application. The lowpass filter corner frequency 456 is set by resistor R₁ and capacitor C in the RC network 406. These components should be made of the same material as the lowpass filter of the low frequency path so that both corner frequencies change together with process variations to keep the crossover ripple low.

The DC feedback 408 can be implemented in analog circuitry or digital circuitry or a combination thereof. The DC feedback 408 provides a very low frequency lowpass filter for keeping the gain of the amplifier offset low. A digital implementation for the DC feedback 408 may be desirable for providing low frequency poles with less chip area and more flexibility to change the corner frequency. For example, at startup it may be desired to have the feedback path with a higher frequency pole to reduce the startup time. Following the startup period the pole could be shifted to a lower frequency, improving the frequency response ripple.

In one particular example embodiment, a current sensor is configured to have a crossover frequency at about 2 kHz with a low frequency pole created by the DC feedback circuit below about 20 Hz. It is understood that the crossover frequency and pole(s) can be set at any practical frequency to meet the needs of a particular application. For example, very low frequency for a DC feedback pole may range from 0.1 Hz to 100 Hz.

Frequently, it is desired to adjust the gain of the signal path of a current sensor to compensate for changes in sensitivity that can be caused by process variation or variations in the packaging process. These slight changes if not compensated for will reduce the accuracy of the sensor.

In the illustrated embodiment, the gain can be adjusted by changing the value of resistor R₂ at the output of the coil. The resistance value of R₂ can be changed to the range of the current sensor. For example, R₂ can be adjusted to change the full-scale current of the sensor from 20 A to a full-scale current of 50 A. A desirable feature of this approach is that while changing R₂ changes the gain of the coil path, it does not alter the corner of the lowpass filter, simplifying the gain trim procedure.

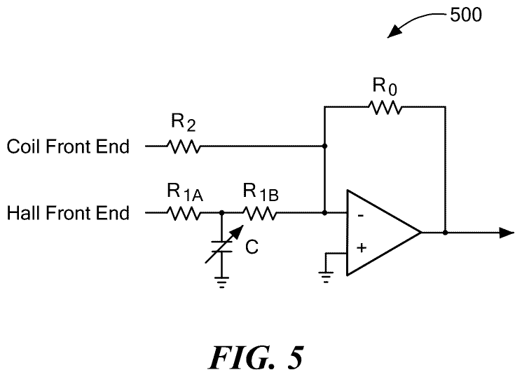

FIG. 5 shows an example implementation 500 of the crossover network 306 of FIG. 3. Since the coil front end path may not require filtering, the crossover network 500 is implemented with resistors R₀ and R₂. The Hall front end path requires a low pass filter and is implemented using resistors R_{1A}, R_{1B}, and capacitor C to form the filter. The material used to implement and the dimensions of this resistor and capacitor should match the material and dimensions of the similar RC components in the coil front end. The Hall front end path gain is set by resistors R_{1A}, R_{1B}, and R₀.

While matching resistor R₁ (R₁=R_{1A}∥R_{1B}) and capacitor C in the cross over circuit to R₁ and C in the coil front end are desirable in matching the corner frequencies in the two paths, it may not achieve a perfect match. Since the RC network is in the feedback of the coil front end, the corner frequency associated with it is weakly dependent on the open loop gain of the opamp. Since the open loop gain can vary slightly with process variation, the frequency response ripple can be reduced by changing the value of C in the cross over circuit 500 to match the altered corner in the coil front end. In embodiments, the capacitor C in the crossover network 500 includes multiple capacitors and switches in parallel that can be controlled to switch capacitors in and out of the circuit to achieve a desired impedance. This may be performed during production test of the part with the selection stored on-chip to further improve the frequency response of the sensor.

While example sensor embodiments are shown having an analog front-end portion and a digital portion, it will be appreciated that the particular delineation of which circuit functions are implemented in an analog fashion or with digital circuitry and signals can be varied. Some of the illustrated circuit functions can be implemented on an integrated circuit sensor and other circuitry and functionality can be implemented on separate circuits (e.g., additional substrates within the same integrated circuit package, or additional integrated circuit packages, and/or on circuit boards).

It understood that additional embodiments can include a variety of sensor types as well as a wide range of sensing elements configurations. For example, a sensor may be configured for applications with different current ranges that are compensated with different number of turns in one or more coils. As noted above, any suitable sensing element, such as coils, Hall element, and MR, e.g., TMR, can be used to meet the needs of a particular application.

Having described preferred embodiments, it will now become apparent to one of ordinary skill in the art that other embodiments incorporating their concepts may be used. Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims. All references cited herein are hereby incorporated herein by reference in their entirety.

It is felt therefore that these embodiments should not be limited to disclosed embodiments, but rather should be limited only by the spirit and scope of the appended claims.

What is claimed is:

1. A sensor, comprising:
a low pass filter to receive a first signal within a first frequency range for a first signal path;
a second low pass filter to receive a second signal within a second frequency range for a second signal path, wherein the second frequency range is higher than the first frequency range; and
a network to receive the filtered first signal and the filtered second signal, wherein the second low pass filter has a corner frequency aligned with a crossover frequency of the network for generating a high pass output signal from the second low pass filter with a flat frequency response above the crossover frequency.

2. The sensor according to claim 1, wherein the first low pass filter is configured to receive the first signal as an output from a magnetic field sensing element.

3. The sensor according to claim 2, wherein the magnetic field sensing element comprises a Hall element.

4. The sensor according to claim 2, wherein the magnetic field sensing element comprises a TMR element.

5. The sensor according to claim 1, wherein the second low pass filter is configured to receive the second signal as an output from one or more coils positioned in relation to a current conductor.

6. The sensor according to claim 1, wherein the second low pass filter is configured to receive the second signal as an output from one or more coils, wherein a gain of the second signal increases with frequency.

7. The sensor according to claim 6, wherein a slope of the gain of the second signal and a roll off of the second low pass filter after the corner frequency produce the flat frequency response above the crossover frequency.

8. The sensor according to claim 1, wherein the second low pass filter comprises an amplifier.

9. The sensor according to claim 8, wherein the second low pass filter includes a DC feedback signal comprising a low frequency low pass filter with a range from 0.1 Hz to 100 Hz.

10. The sensor according to claim 9, wherein the second low pass filter includes an RC feedback network for the amplifier.

11. The sensor according to claim 10, further including an adjustable impedance component coupled between the coil and the amplifier for adjusting a gain of the amplifier.

12. The sensor according to claim 1, wherein the network includes a summing amplifier to receive the filtered first and second signals.

13. The sensor according to claim 1, wherein the network comprises an amplifier to provide the first low pass filter.

14. The sensor according to claim 13, wherein the network includes a gain for the first signal set by an RC network coupled to the amplifier.

15. The sensor according to claim 1, wherein passive components in the first and second signal paths are matched in material and/or dimensions.

16. A method, comprising:
low pass filtering, with a first low pass filter, a first signal within a first frequency range for a first signal path;
second low pass filtering, with a second low pass filter, a second signal within a second frequency range for a second signal path, wherein the second frequency range is higher than the first frequency range; and
receiving, with a network, the filtered first signal and the filtered second signal, wherein the second low pass filter has a corner frequency aligned with a crossover frequency of the network for generating a high pass output signal from the second low pass filter with a flat frequency response above the crossover frequency.

17. The method according to claim 16, wherein the first low pass filter receives the first signal as an output from a Hall element.

18. The method according to claim 16, wherein the second low pass filter receives the second signal as an output from one or more coils positioned in relation to a current conductor.

19. The method according to claim 16, wherein the second low pass filter receives the second signal as an output from one or more coils, wherein a gain of the second signal increases with frequency.

20. The method according to claim 19, wherein a slope of the gain of the second signal and a roll off of the second low pass filter after the corner frequency produce the flat frequency response above the crossover frequency.

21. The method according to claim 16, wherein the second low pass filter comprises:
an amplifier;
a DC feedback signal comprising a low frequency low pass filter with a range from 0.1 Hz to 100 Hz; and
an RC feedback network for the amplifier.
